(19) United States
(12) Patent Application Publication
(10) Pub. No.: US 2014/0284659 A1
(43) Pub. Date: Sep. 25, 2014

(54) Transient Voltage Suppressor, Design and Process

(71) Applicant: Bourns, Inc., Riverside, CA (US)

(72) Inventors: Tao Wei, Los Gatos, CA (US); Andrew J. Morrish, Saratoga, CA (US)

(21) Appl. No.: 14/222,233

(22) Filed: Mar. 21, 2014

Related U.S. Application Data
(60) Provisional application No. 61/803,880, filed on Mar. 21, 2013.

(51) Int. Cl. H01L 29/747

(52) U.S. Cl. CPC H01L 29/747
USPC 257/173

(57) ABSTRACT

A transient voltage suppressor (TVS) device design compatible with normal IC wafer process is provided. Instead of a thick base that requires double-sided wafer processing, a much thinner base with a modulated doping profile is used. In this base, a high doping layer is sandwiched by two lower layers of the same or different doping. The base is then sandwiched by two electrodes having opposite doping relative to the base center layer. In the base, the two lower doping layers will determine the breakdown voltage. The middle layer is used to reduce the transistor gain and thus produce an acceptable snapback characteristic. The presence of the higher doped middle layer allows the total base width to be as low as 5 μm for a breakdown voltage of about 30 V.

### CROSS REFERENCE TO RELATED APPLICATIONS

This application claims the benefit of U.S. provisional patent application 61/803,880, filed on Mar. 21, 2013, and hereby incorporated by reference in its entirety.

### FIELD OF THE INVENTION

This invention relates to transient voltage suppression devices.

### BACKGROUND

A bi-directional transient voltage suppressor (TVS) device can be realized as two diodes connected back to back in series. When a sufficiently large voltage is applied to such a structure, one of the diodes is forward biased, and the other diode breaks down. If the polarity of the applied voltage is reversed, the diodes exchange their roles. Thus, such a device can act as a transient voltage suppressor for transients of both polarities. In practice, a TVS device is often realized as a single monolithic device, as opposed to two independent diodes, which has the added advantage that the two back-to-back diodes then act as a low gain bipolar transistor. This approach can reduce cost and provide improved performance. In particular, a low level of transistor gain can significantly decrease the on-resistance of a TVS device.

An exemplary TVS device is in fact an open base bipolar transistor, with breakdown voltage normally at about 20-30V. The transistor is designed to have a limited amount of snap-back in the breakdown IV characteristic. This characteristic prevents applied voltage from increasing too much with increasing current, thereby helpfully limiting surge voltage, reducing power dissipation and improving device ruggedness. For higher protection voltage TVS type devices, multiple TVS devices may be cascaded in assembly to produce a higher breakdown voltage device.

An exemplary device of this kind is shown on FIG. 1A. FIG. 1B shows an exemplary doping profile for the structure of FIG. 1A. Such devices typically include a P-type base 104 as thick as about 200 μm, sandwiched by two N+ layers 102 and 106 acting as collector and emitter (see FIGS. 1A-B). Simulation shows this device has a near straight-up I-V characteristic at breakdown at 31V, with voltage increases less than 1V while current increases by six orders of magnitude, as shown on FIG. 2A (log scale) and FIG. 2B (linear scale).

For this kind of structure, a base thicker than about 100 μm is needed to produce an acceptable near straight-up I-V characteristic. However, a thicker base increases the series resistance and causes current to increases with voltage beyond breakdown (FIG. 2B). A thinner base can help in that aspect but would result in a higher beta and larger snap-back, which is not desirable in this application, as this may cause the device to sustain conduction at lower than the supply rail voltage when protecting power supply outputs.

The doping concentration in the base region is also important. If the doping level is high, the breakdown voltage is lower, but the gain is reduced, which, in turn, reduces the amount of snap-back. If the doping level is lower, higher breakdown voltage is achieved, but the gain increases due to the lower doped base region, and the degree of snapback becomes too great. For this reason, a breakdown voltage of 25-35V is typically chosen as a design compromise, because there is no means of independently adjusting gain and breakdown voltage.

Typical semiconductor wafers are originally as thick as 600 μm. Thus, fabrication of such TVS devices proceeds by first thinning down the wafer by grinding to about 200 μm, and then processing the thinned wafer on both the front and back sides. Because the wafer is thinner than normal, and is processed on both sides, wafer handling has to be done very carefully which usually increases processing cost. These requirements also make for a difficult and specialized process flow, which many fabrication facilities cannot handle.

Accordingly, it would be an advance in the art to provide TVS structures that alleviate the above-identified difficulties.

### SUMMARY

In this work a TVS device design compatible with normal IC wafer process is provided. Instead of a 200 μm thick base, a much thinner base with a modulated doping profile is used. In this base, a high doping (e.g., P+ type) layer is sandwiched by two layers having lower doping of the same or different doping type (e.g., P-type or N-type). The base is then sandwiched by two opposite doping (N+) electrodes. In the base, the two lower doping layers will determine the breakdown voltage and they have to be wider than the depletion distance at breakdown. The middle layer is used to reduce the bipolar beta (i.e., the transistor gain) and thus produce an acceptable snapback characteristic. The presence of the higher doped middle layer allows the total base width to be as low as 5 μm for a breakdown voltage of about 30V. The base can be built from modulated doped epitaxial layers on an N+ substrate wafer which can be of normal thickness in a conventional IC fabrication facility, or by use of an implant/epitaxy combination. The case of a P-type base and N-type electrodes is described herein, but configurations with an N-type base and P-type electrodes are also possible.

### BRIEF DESCRIPTION OF THE DRAWINGS

FIGS. 1A-B show a prior art transient voltage suppressor configuration.

FIGS. 2A-B show simulation results relating to the example of FIGS. 1A-B.

FIG. 3A shows an exemplary embodiment of the invention.

FIG. 3B shows a doping profile relating to the example of FIG. 3A.

FIGS. 4A-B show simulation results relating to the example of FIGS. 3A-B.

FIG. 5 shows another embodiment of the invention.

FIG. 6A shows an exemplary doping profile relating to the embodiment of FIG. 5.

FIG. 6B shows simulation results relating to the example of FIG. 6A.

FIG. 7 shows a further embodiment of the invention.

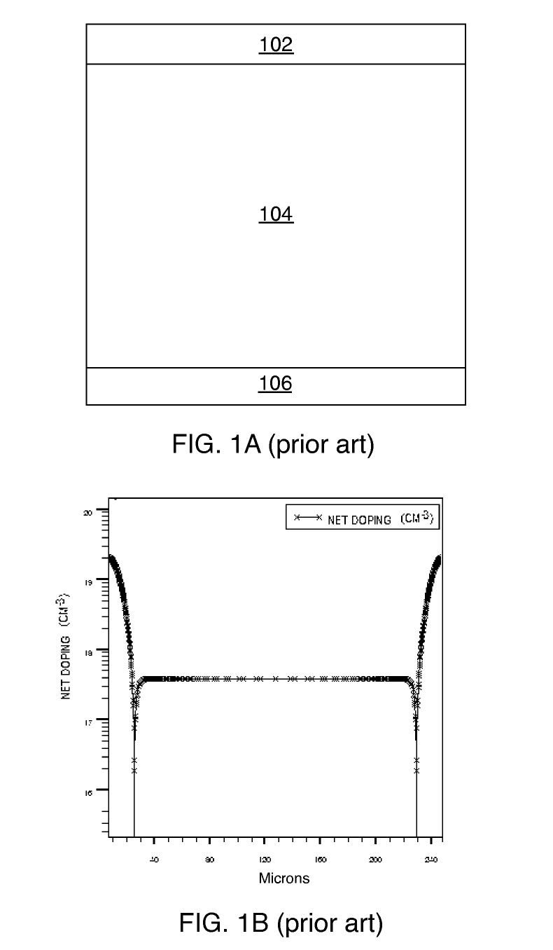

### DETAILED DESCRIPTION

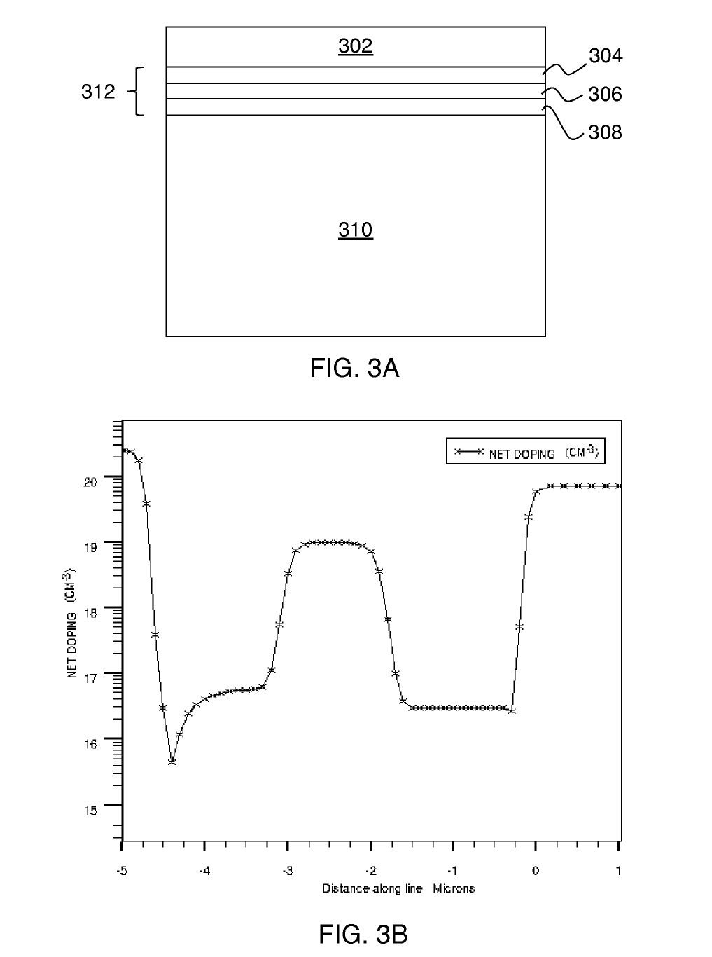

FIG. 3A shows an exemplary embodiment of the invention. Here a central semiconductor region 312 is sandwiched between two side semiconductor regions 302 and 310. Central region 312 includes a first layer 306 sandwiched between second layer 304 and third layer 308 that are less heavily doped than first layer 306. These first, second and third layers can all have the same doping type. Alternatively, the doping type of second and third layers 304 and/or 308 can differ from the doping type of layer 306. The doping type of layer 306 is opposite the doping type of side semiconductor regions 302 and 310. Side regions 302 and 310 can be single layer structures (e.g., N+ or P+ electrodes) or multi-layer structures (e.g., N+/N− or P+/P− electrodes).

A thickness and a doping level of first layer 306 are selected to provide a predetermined transistor gain in order to achieve a predetermined amount of snap-back, thereby reducing an on-resistance of the apparatus. The doping level of first layer 306 is preferably greater than about 10¹⁷ cm⁻³. The thickness of first layer 306 is preferably between about 1 μm and about 5 μm. The resulting predetermined transistor gain is preferably between about 0.1 and about 2.

Thicknesses and doping levels of the second and third layers 304 and 308 are individually selected to provide predetermined break down voltages for both polarities of applied voltage. The doping level of second layer 304 is preferably less than about 10¹⁷ cm⁻³. The doping level of third layer 308 is preferably less than about 10¹⁷ cm⁻³. The thickness of second layer 304 is preferably between about 1 μm and about 10 μm. The thickness of third layer 308 is preferably between about 1 μm and about 10 μm.

Although in many applications symmetric bi-directional operation is required, in some applications, asymmetry is preferred. Because the avalanche voltage in each direction is separately controlled by the doping on either side of the center high doping region, the avalanche voltage in each direction can be independently set by choice of the doping. More specifically, the predetermined break down voltages can be substantially the same for positive and negative polarities of applied voltage. Alternatively, the predetermined break down voltages can be different for positive and negative polarities of applied voltage.

FIG. 3B shows a doping profile relating to the example of FIG. 3A. In this example, the central region is P-type, and the side semiconductor regions are N-type.

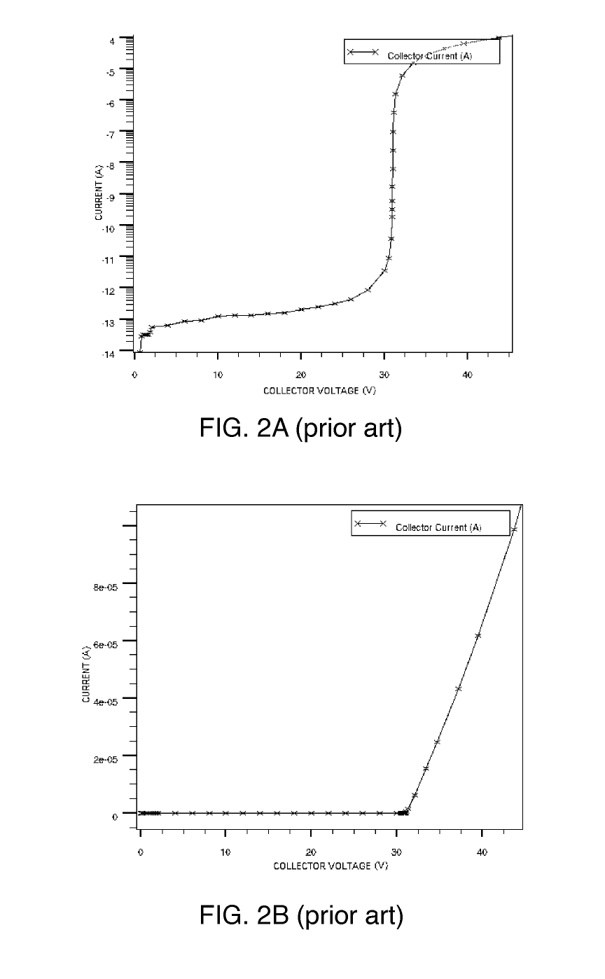

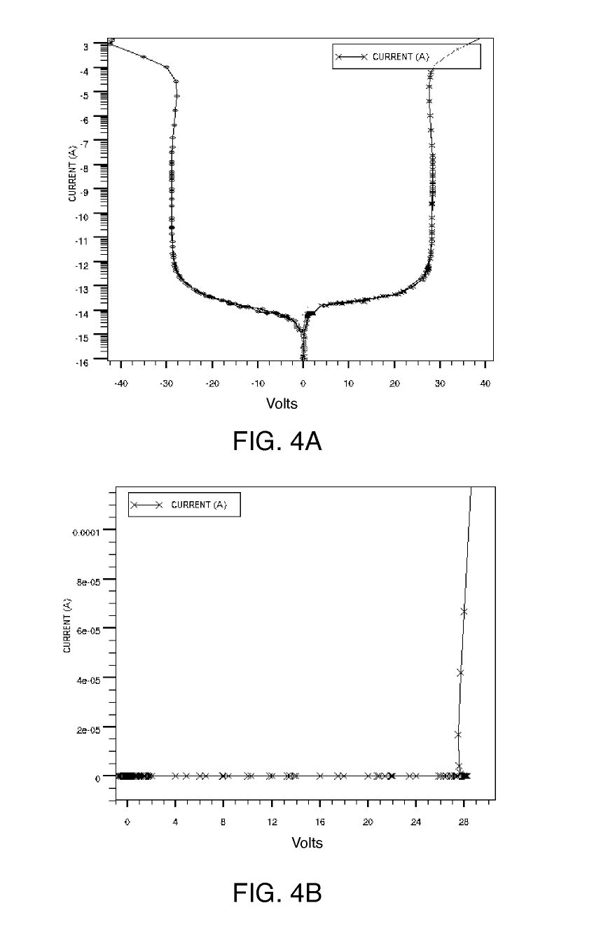

FIGS. 4A-B show simulation results relating to the example of FIGS. 3A-B. These results are similar to, but better than the characteristic of FIGS. 2A-B. By introducing a very slight snap-back, voltage increase can be less than 1V with current increasing over eight orders of magnitude. In fact, by varying the thickness and doping density of the middle layer 306, the snap-back characteristic can be manipulated to the desired pattern with relative ease, virtually independently of the breakdown voltage. Another significant advantage is the significantly lower resistance beyond breakdown due to the narrower base (FIG. 4B), which is about one order of magnitude lower than that in FIGS. 2A-B. Because the resistive voltage drop directly affects the amount of power dissipated, lower slope resistance will result in lower power per unit area. Lower slope resistance potentially allows a significantly smaller device to be made for an equivalent power density, with perhaps 10-20% more die for wafer, and hence lower cost, and, if desirable, with a smaller footprint.

This structure can be made by growing P-type epitaxial layers on a N+ substrate, followed by a N+ implant. The modulated doping base can be either generated during epitaxial growth, by switching to a higher doping concentration midway through epitaxial growth, and then back to the lower doping concentration. An alternative is to grow a first low doping epitaxial layer, followed by blanket implantation by Boron to create the higher doping middle layer, and then growing a second low doping epitaxial layer, such as a conventional buried layer formed in many other types of devices.

Although this design extends itself to being used for single higher voltage structures, it is sometime beneficial to limit the energy within a single junction in order to prevent excessive temperature. For this reason multiple series junctions may still be used for some high voltage applications. This design can be extended to include multiple transistors in series, by repeating the same structure, each structure separated by a heavily doped N+ layer. There are two main advantages of cascading multiple low voltage devices versus a single high voltage TVS device:
1) higher short duration power handling capability, as a result of dissipating the power over multiple junctions instead of a single one; and
2) better control of the “snap-back” (sometimes known as “fold-back”) characteristic which has been generally found to be optimal in the region of approximately 25-35V avalanche voltage for conventional TVS designs.

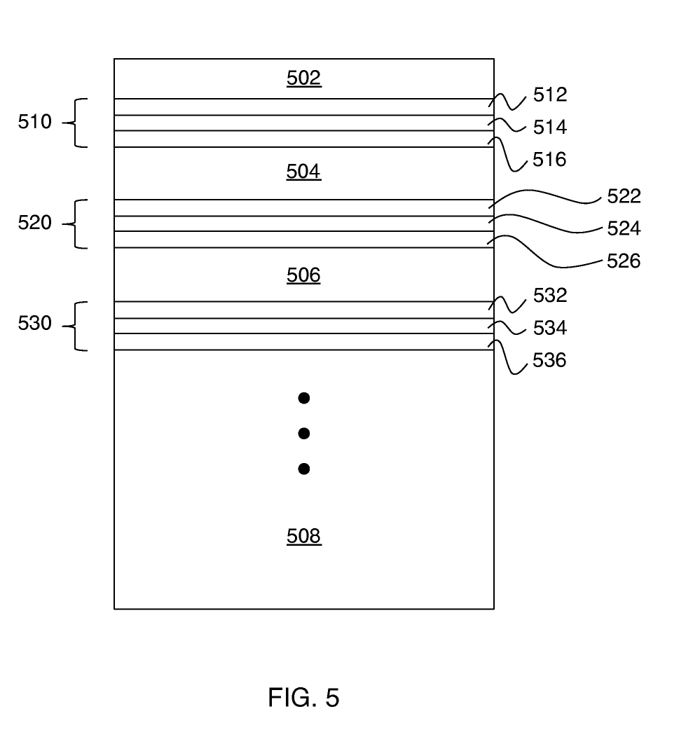

FIG. 5 shows an example of this multiple transistor TVS approach.

In the example of FIG. 5, the apparatus includes an alternating sequence of regions (502, 510, 504, 520, 506, 530, 508) including layers having opposite doping type. Here the first and last regions in this sequence (i.e., regions 502 and 508 both have a first doping type. Because this sequence of regions is alternating with respect to doping type, it follows that regions 504 and 506 also include a layer having the first doping type, while regions 510, 520, and 530 all include a layer having a second doping type opposite the first doping type. Each region including a layer with the second doping type includes a first layer sandwiched between second and third layers that are less heavily doped than the first layer. Here first layer 514 of region 510 is sandwiched between second layer 512 and third layer 516 of region 510. Similarly, first layer 524 of region 520 is sandwiched between second layer 522 and third layer 526 of region 520, and first layer 534 of region 530 is sandwiched between second layer 532 and third layer 536 of region 530. These first, second and third layers can all have the same doping type. Alternatively, the doping type of second and third layers 512, 522, 532 and/or 516, 526, 536 can differ from the doping type of first layers 514, 524, 534. First layers 514, 524, 534 have the second doping type.

Thicknesses and doping levels of the first layers are selected to provide a predetermined transistor gain in order to achieve a predetermined amount of snap-back, thereby reducing an on-resistance of the apparatus. The doping levels of these first layers (e.g., 514, 524, 534) are preferably greater than about 10¹⁷ cm⁻³. The thicknesses of these first layers (e.g., 514, 524, 534) are preferably between about 1 μm and about 5 μm. The resulting predetermined transistor gains are preferably between about 0.1 and about 2 for the series transistors.

Thicknesses and doping levels of the second and third layers are individually selected to provide predetermined break down voltages for both polarities of applied voltage. The doping levels of these second layers (e.g., 512, 522, 532) are preferably less than about 10¹⁷ cm⁻³. The doping levels of these third layers (e.g., 516, 526, 536) are preferably less than about 10¹⁷ cm⁻³. The thicknesses of these second layers (e.g., 512, 522, 532) are preferably between about 1 μm and about 10 μm. The thicknesses of these third layers (e.g., 516, 526, 536) are preferably between about 1 μm and about 10 μm.

Regions including a layer having the first doping type that are sandwiched between regions including a layer having the second doping type (e.g., 504 and 506 on FIG. 5) preferably have a doping level greater than about 10¹⁷ cm⁻³. Heavy doping for such intermediate layers is preferred in order to reduce transistor gain and to prevent formation of parasitic thyristor devices which could interfere with TVS operation.

The example of FIG. 5 shows a 3X structure (three transistors in series). Any number of transistors can be put in series according to this pattern to provide a TVS structure.

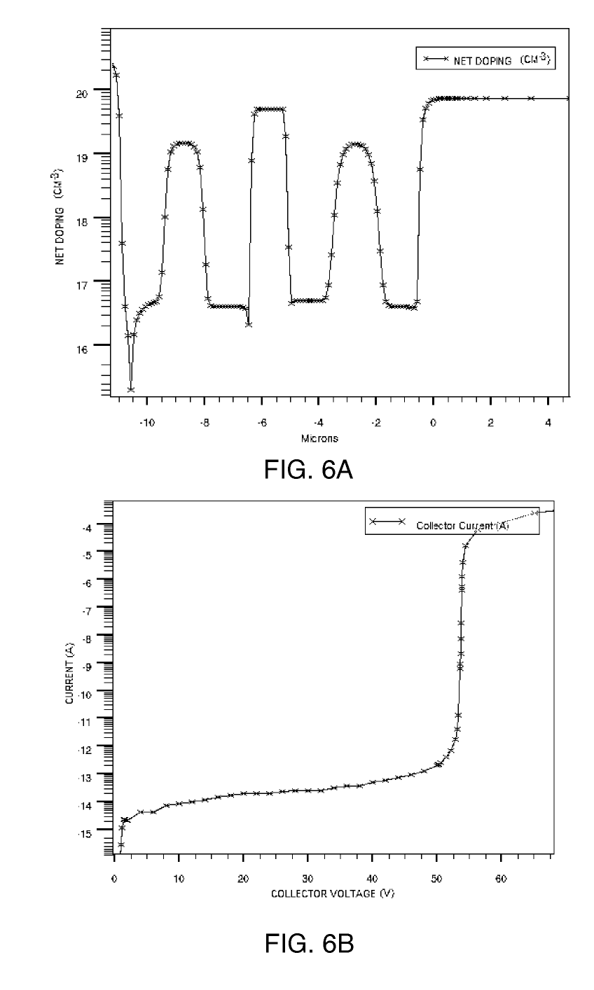

An example of a 2X structure is shown in FIG. 6A. It is basically a back-to-back TVS that doubles the breakdown voltage, as seen on the simulation results of FIG. 6B. Compared to a single device with two times the breakdown voltage, this back-to-back structure has the advantage of spreading out power dissipation by splitting the power to two different junctions. It is thus expected to be able to handle similar current density while voltage doubles. As shown in FIG. 6A, the whole structure can be made as thin as 12 μm. Even a 4X structure can be made to be less than 30 μm thick. Such a thickness will allow the device termination to be produced by the conventional method of dry etch plus passivation. Clearly, this approach of multiple TVS devices in series can reduce production cost significantly.

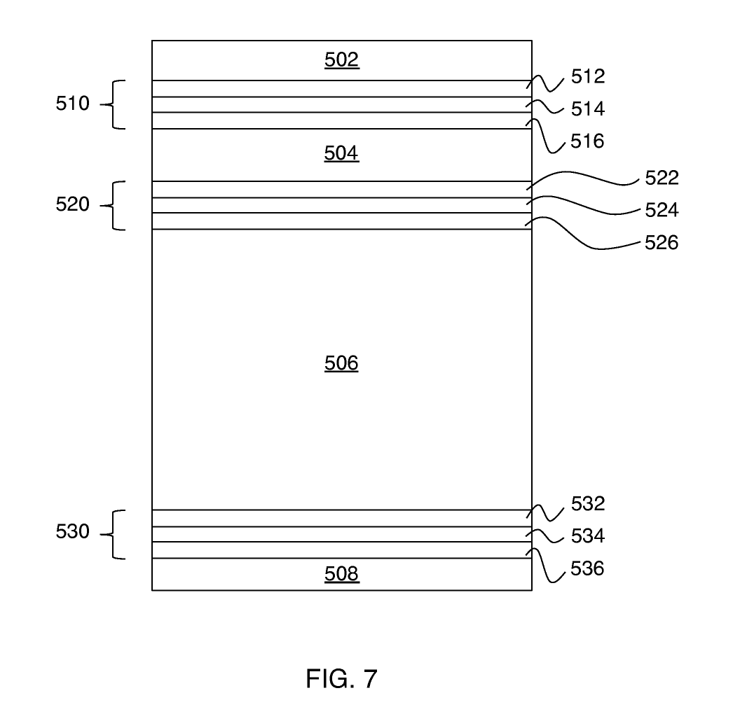

Similarly, when double side process capability is available, the whole structure could be repeated on the back side. This produces another back-to-back TVS that doubles the total breakdown voltage. Compared to a single side device, this back-to-back structure has the advantage of dissipating power near two opposite surfaces of the wafer that are far away from each other, which suggest the ability to able to handle similar current density with 2X voltage. Again, this double side, multiple TVS approach can reduce production cost significantly. More specifically, all first layers having the second doping type can be disposed near a single surface of a semiconductor wafer (e.g., as shown on FIG. 5). Alternatively, some first layers having the second doping type can be disposed near the top surface of a semiconductor wafer and other first layers having the second doping type can be disposed near the bottom surface of a semiconductor wafer, as shown on FIG. 7.

1. Apparatus for transient voltage suppression, the apparatus comprising:
a central semiconductor region;
two side semiconductor regions, wherein the central region is sandwiched between the two side regions;
wherein the central region includes a first layer sandwiched between second and third layers that are less heavily doped than the first layer;
wherein a doping type of the side semiconductor regions is opposite a doping type of the first layer;
wherein a thickness and a doping level of the first layer are selected to provide a predetermined transistor gain in order to achieve a predetermined amount of snap-back, thereby reducing an on-resistance of the apparatus;
wherein thicknesses and doping levels of the second and third layers are individually selected to provide predetermined break down voltages for both polarities of applied voltage.

2. The apparatus of claim 1, wherein a doping level of the first layer is greater than about 10¹⁷ cm⁻³.

3. The apparatus of claim 1, wherein a doping level of the second layer is less than about 10¹⁷ cm⁻³.

4. The apparatus of claim 1, wherein a doping level of the third layer is less than about 10¹⁷ cm⁻³.

5. The apparatus of claim 1, wherein a thickness of the first layer is between about 1 μm and about 5 μm.

6. The apparatus of claim 1, wherein a thickness of the second layer is between about 1 μm and about 10 μm.

7. The apparatus of claim 1, wherein a thickness of the third layer is between about 1 μm and about 10 μm.

8. The apparatus of claim 1, wherein the predetermined transistor gain is between about 0.1 and about 2.

9. The apparatus of claim 1, wherein the predetermined break down voltages are substantially the same for positive and negative polarities of applied voltage.

10. The apparatus of claim 1, wherein the predetermined break down voltages are different for positive and negative polarities of applied voltage.

11. Apparatus for transient voltage suppression, the apparatus comprising:
an alternating sequence of regions including layers of opposite doping type;
wherein the sequence of regions has a first region and a last region that both have a first doping type;
wherein each region including a layer having a second doping type opposite the first doping type includes a first layer sandwiched between second and third layers that are less heavily doped than the first layer, wherein the first layer has the second doping type;
wherein thicknesses and doping levels of the first layers are selected to provide a predetermined transistor gain in order to achieve a predetermined amount of snap-back, thereby reducing an on-resistance of the apparatus;
wherein thicknesses and doping levels of the second and third layers are individually selected to provide predetermined break down voltages for both polarities of applied voltage.

12. The apparatus of claim 11, wherein all first layers having the second doping type are disposed near a single surface of a semiconductor wafer.

13. The apparatus of claim 11, wherein some first layers having the second doping type are disposed near a top surface of a semiconductor wafer and wherein other first layers having the second doping type are disposed near a bottom surface of a semiconductor wafer.

14. The apparatus of claim 11, wherein regions including a layer having the first doping type that are sandwiched between regions including a layer having the second doping type have a doping level greater than about 10¹⁷ cm⁻³.
